(19) United States
(12) Patent Application Publication
(10) Pub. No.: US 2026/0143641 A1
(43) Pub. Date: May 21, 2026

(54) Constructional Layout for Distributing Power Dissipation to Both Sidewalls

(71) Applicant: Siemens Aktiengesellschaft, Muenchen (DE)

(72) Inventors: Martin PETRICEK, Hollabrunn (AT); Daniel PORTISCH, Poysdorf (AT)

(21) Appl. No.: 19/311,000

(22) Filed: Aug. 27, 2025

(30) Foreign Application Priority Data
Aug. 28, 2024 (EP) 24197083

(51) Int. Cl. H05K 7/20; H05K 1/02

(52) U.S. Cl. CPC H05K 7/2049; H05K 1/0203; H05K 7/20509; H05K 7/209; H05K 2201/066; H05K 2201/10598

(57) ABSTRACT

An electronic device formed as a power supply system, includes a housing, a first electronic subassembly forming a first power supply unit that includes a first heatsink, and a second electronic subassembly forming a second power supply unit that includes a second heatsink, where the first and the second electronic subassemblies are arranged in the housing, and the first heatsink and the second heatsinks are pressed internally against the housing via pressing elements.

### BACKGROUND OF THE INVENTION

### 1. Field of the Invention

The present invention relates generally to the field of electrical engineering and, more particularly, to the power electronics sector and, specifically, relates to an electronic device, in particular to a power supply system.

### 2. Description of the Related Art

In the prior art, in electronic devices having more than one laterally arranged printed circuit board, the populated printed circuit boards are screwed onto respective external heatsinks or cooling plates and subsequently the printed circuit boards are screwed to one another. This combination of heatsink-printed circuit board-printed circuit board-heatsink is then inserted into a housing made of metal. However, due to mechanical tolerances, the heatsinks are not in contact internally over the entire surface with the sidewalls of the housing. This results in poor cooling performance. This must be tolerated or improved via additional complex and cost-intensive cooling measures, such as heatpipes.

### SUMMARY OF THE INVENTION

It is an object of the present invention to provide improved cooling of an electronic device without elaborate time-consuming or cost-intensive measures.

This and other objects and advantages are achieved in accordance with the invention by an electronic device, in particular a power supply system, comprising a housing, a first electronic subassembly, in particular a first power supply unit, comprising a first heatsink, and a second electronic subassembly, in particular a second power supply unit, comprising a second heatsink, where the first and second electronic subassemblies are arranged in the housing, and the first and second heatsinks are pressed internally against the housing via pressing elements.

An optimal distribution of the power dissipation in the electronic device occurs as a result of the power supply system being subdivided into a first and second electronic subassemblies. The pressing elements enable the heatsinks to be pressed internally against the housing in a tightly fitting manner, thereby compensating for component tolerances, in particular of the housing.

It is advantageous if at least one pressing element is formed as a plug that is incorporated in the first and/or second electronic subassembly, where the plug interacts with recesses in the housing.

Owing to the embodiment of at least one pressing element as a plug, an optimal pressing of the electronic subassemblies internally against the housing is achieved once the electronic subassemblies have been inserted into the housing. In this arrangement, the plug is preferably formed by an insulating body, but can also be formed by a printed circuit board or a heatsink. The plug is structured to be elastic. The plug can have a bevel or overrun ramp. The bevel facilitates the insertion of the plug into a recess in the housing. The interaction of the plug with a recess works such that the plug presses against an inner edge of the recess and thereby urges the electronic subassembly or the heatsink outward and presses the heatsink inward against the housing.

It is advantageous if the electronic device further comprises a connecting board via which the first and the second electronic subassemblies are electrically and mechanically connected to one another, and at least one pressing element is formed as a spring element that is incorporated in the connecting board.

Implementing the pressing element as a spring element constitutes a further advantageous opportunity to press the heatsinks internally against the housing and in this way to compensate for component tolerances of the housing and ensure an optimal transfer of heat from the heatsink to the housing.

It is advantageous if the connecting board is divided in two parts, i.e., a first partial connecting board and a second partial connecting board, and the spring element produces a spring-loaded engagement between the first and the second partial connecting board. The pressing of the heatsinks internally against the housing is improved further as a result of this measure.

It is advantageous if the spring element is formed by an elastic extension of the first partial connecting board, which elastic extension interacts with the second partial connecting board. A particularly simple fabrication of the spring element without additional components is possible as a result of this measure.

It is advantageous if the first and the second heatsink are pressed against opposite sidewalls of the housing. The distribution of the power dissipation in the housing is optimized further as a result of this measure. Accordingly, the sidewalls of the housing can be used in the best possible way for providing cooling. Furthermore, this keeps the heatsinks separated as far as possible from one another, thus preventing a reciprocal heating.

It is advantageous if the first and the second electronic subassembly have an identical electrical functionality and are connected in parallel. By an identical electrical functionality is to be understood that the first and the second electronic subassembly fulfill an identical intended purpose. For example, each of the two electronic subassemblies is a power supply unit. As a result, it is possible to subdivide an electronic device or a power supply system into two electronic subassemblies or two power supply units, each of which provides half of a required nominal current or half of a required nominal power of the electronic device or the power supply system. The subdivision into two electronic subassemblies or two power supply units then allows the electronic subassemblies to be disposed in a spatially separate arrangement to provide an optimal distribution of the power dissipation in the electronic device.

It is advantageous if the electronic device further comprises a first fastening element that is arranged in a positive-locking manner in a first printed circuit board of the first electronic subassembly or in a second printed circuit board of the second electronic subassembly, which has a thread and at least one spring arm, and which is screwed to the first or second electronic subassembly such that a force is exerted by the first fastening element, in particular by the at least one spring arm, where the force presses the first printed circuit board against the first heatsink or the second printed circuit board against the second heatsink.

An optimal transfer of heat from the printed circuit board to the heatsink is ensured as a result of this measure.

It is advantageous if the electronic device further comprises a second fastening element that is secured at the sides to a printed circuit board and via which an electronic component between the heatsink and the second fastening element can be pressed against the heatsink. An improved contacting of electronic components with the heatsink is achieved as a result of this measure.

It is advantageous if the electronic device is a power supply system, if the first electronic subassembly is a first power supply unit and if the second electronic subassembly is a second power supply unit. Particularly advantageously, as a result of this measure, a power supply system is formed, the two power supply units of which are arranged in a distributed manner in the housing and consequently the power losses of the two power supply units are distributed in the electronic device.

The objects and advantages are further achieved in accordance with the invention by a method for assembling an electronic device, where the first and the second electronic subassembly are inserted into the housing and the first heatsink and the second heatsink are pressed internally against the housing via pressing elements.

An advantageous effect of the inventive method is that component tolerances of the housing are compensated for and the heatsinks are pressed internally against the housing and make contact internally completely or over the entire surface with the housing. The method can be performed easily and in an automated manner.

It is advantageous if the first and the second partial connecting board are electrically connected to one another. The effect of connecting the partial connecting boards together after the electronic subassemblies have been inserted into the housing is that the pressing element, formed as a spring element, can press the heatsinks against the housing first before this position is fixed by the connection of the partial connecting boards.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention as well as further advantageous embodiments of the invention according to the features of the dependent claims are explained in more detail below with reference to exemplary embodiments illustrated in the figures, in which:

FIG. 1 shows an exemplary constructional layout of an electronic device in accordance with the invention in a first illustration without heatsinks and housing;

FIG. 2 shows an exemplary constructional layout of an electronic device in accordance with the invention in a second illustration with heatsinks and without housing;

FIG. 3 shows an exemplary constructional layout of an electronic device in accordance with the invention in a third illustration with heatsinks and without housing;

FIG. 4 shows an exemplary constructional layout of an electronic device in accordance with the invention in a fourth illustration with heatsinks in a housing;

FIG. 5 shows an exemplary first detail view of a pressing element formed as a plug;

FIG. 6 shows an exemplary second detail view of a pressing element formed as a plug;

FIG. 7 shows an exemplary illustration of a connecting board having a pressing element formed as a spring element;

FIG. 8 shows an exemplary illustration of a step of the method for assembling the electronic device;

FIG. 9 shows a detail view of a pressing element formed as a spring element,

FIG. 10 shows an exemplary illustration of the connecting board of the electronic device with front lid (not shown);

FIG. 11 shows an exemplary first illustration of a first fastening element;

FIG. 12 shows an exemplary second illustration of a first fastening element;

FIG. 13 shows an exemplary third illustration of a first fastening element;

FIG. 14 shows an exemplary fourth illustration of a first fastening element;

FIG. 15 shows an exemplary first illustration of a second fastening element;

FIG. 16 shows an exemplary second illustration of a second fastening element;

FIG. 17 shows an exemplary third illustration of a second fastening element; and

FIG. 18 is a flowchart of the method in accordance with the invention.

### DETAILED DESCRIPTION OF THE EXEMPLARY EMBODIMENTS

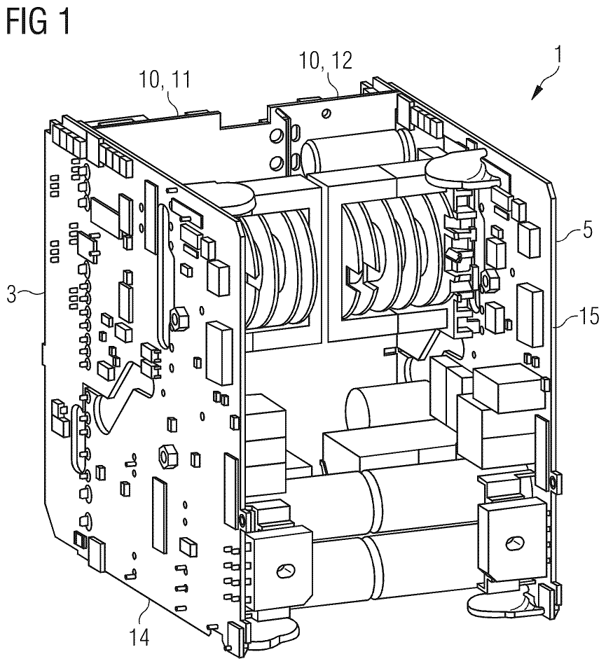

FIG. 1 shows an exemplary constructional layout of an electronic device 1 in accordance with the invention in a first illustration without heatsinks and housing. The electronic device 1 is shown, which in this exemplary embodiment is a power supply system. FIG. 1 further shows a first electronic subassembly 3 and a second electronic subassembly 5, which in this exemplary embodiment are a first power supply unit 3 and a second power supply unit 5. The first electronic subassembly 3 comprises a first printed circuit board 14 and the second electronic subassembly 5 comprises a second printed circuit board 15. The first printed circuit board 14 and the second printed circuit board 15 are populated with different electronic components. A connecting board 10 is also shown. The two power supply units 3, 5 are electrically and mechanically connected to one another via the connecting board 10. In this example, the electronic subassemblies 3, 5, in particular their printed circuit boards 14, 15, are arranged parallel to one another and along the sidewalls of the housing 2, while the connecting board 10 stands normally on each of the electronic subassemblies 3, 5, in particular their printed circuit boards 14, 15.

In this example, the first power supply unit 3 and a second power supply unit 5 are connected in parallel and together form a power supply system. A 40 A power supply system is in this case divided into two 20 A power supply units 3, 5. This effects the distribution of the power dissipation as a result of the 40 A power supply system being implemented via two 20 A power supply units 3, 5, where one sidewall of the housing 2 in each case handles the complete cooling of a 20 A power supply unit 3, 5, which in turn leads to the dissipated power being distributed via both sides of the housing 2. The two electronic subassemblies 3, 5 are in this case disposed in a mirror-inverted arrangement in order to accomplish the cooling outwardly to the left and outwardly to the right, respectively.

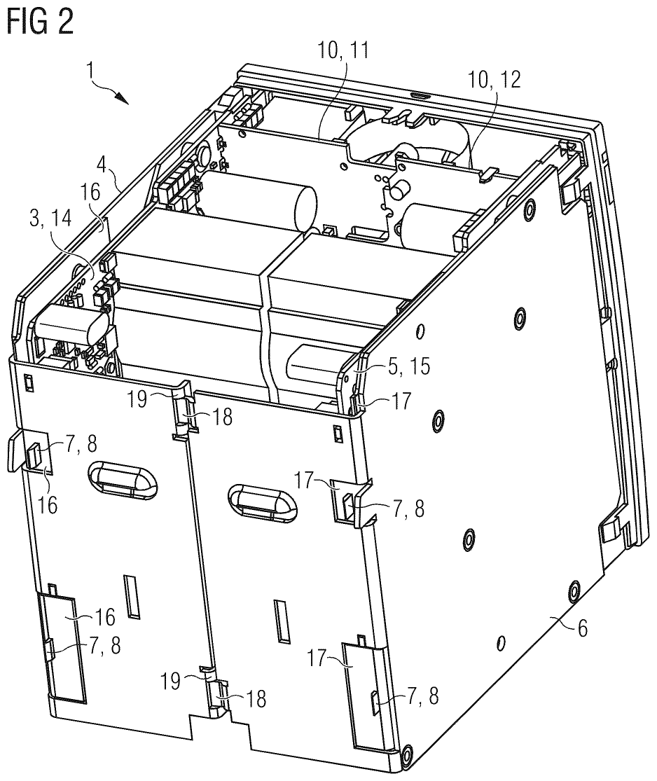

FIG. 2 shows an exemplary constructional layout of an electronic device 1 in accordance with the invention in a second illustration with heatsinks 4, 6 and without housing 2. The first electronic subassembly 3 comprising the first printed circuit board 14 and the second electronic subassembly 5 comprising the second printed circuit board 15 are shown. The first heatsink 4 and the second heatsink 6 are also shown. The heatsinks 4, 6 are in this case implemented as L-shaped heatsinks that each extend along opposite sidewalls of the housing 2 (not shown) and in each case along the first printed circuit board 14 and the second printed circuit board 15. Also shown are a first insulating body 16 and a second insulating body 17. The insulating bodies 16, 17 are implemented as insulating plates, each of which extends at least partially between the first printed circuit board 14 and the first heatsink 4 as well as between the second printed circuit board 15 and the second heatsink 6. The insulating bodies 16, 17 have openings (not shown) in which ceramic insulation inserts are inserted which are configured for transferring heat. The ceramic insulation inserts each make contact both with a printed circuit board 14, 15 and with a heatsink 4, 6 and ensure a transfer of heat between the respective printed circuit board 14, 15, in particular from thermally stressed electronic components on the respective printed circuit board 14, 15, to the respective heatsink 4, 6. The first printed circuit board 14, the first insulating body 16 and the first heatsink 4 are connected to one another, in the example via a screwed joint. Similarly, the second printed circuit board 15, the second insulating body 17 and the second heatsink 6 are connected to one another, in this example via a screwed joint. These connections or screwed fittings are already completed before the electronic subassemblies 3, 5 are installed in the housing 2.

In the illustrated non-assembled state, the two electronic subassemblies 3, 5 are movable toward each other. At one of their ends, the heatsinks 4, 6 together comprise a system composed of clip 18 and bracket 19, where the clip 18 is inserted into the bracket 19. With the clip 18 and the bracket 19, it is ensured that the electronic subassemblies are movable toward each other and away from each other in the non-assembled state, i.e., prior to and during an installation in the housing 2.

A plurality of pressing elements 7 are also shown. In this example, four pressing elements 7 are implemented as plugs 8. The plugs 8 in this example are part of the insulating bodies 16, 17. The plugs 8 point toward a rear side of the device 1 or the housing 2 (not shown). The plugs 8 have bevels that facilitate their insertion into the housing 2. This is explained further in relation to FIGS. 4-7.

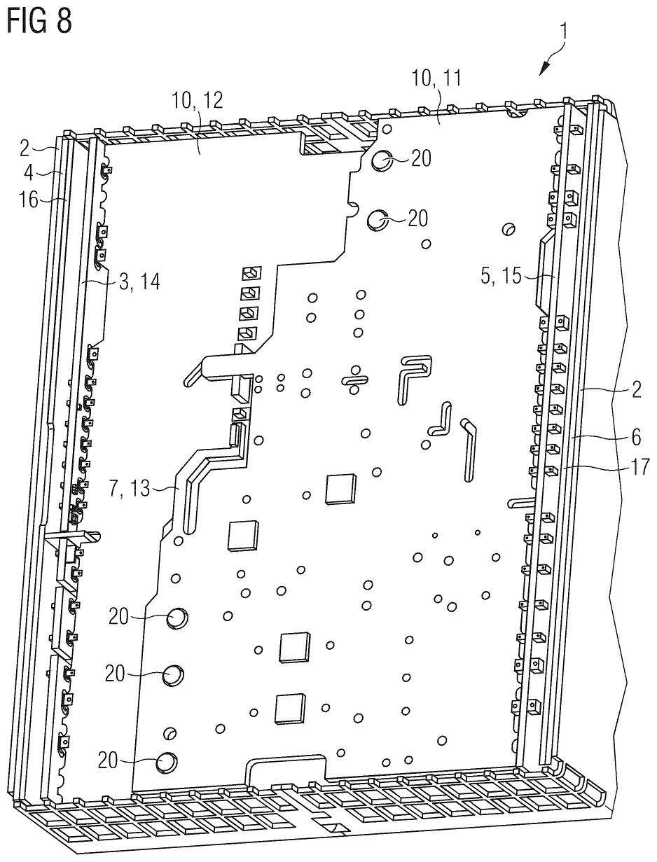

Also shown is a connecting board 10 via which the first and the second electronic subassembly 3, 5 are electrically and mechanically connected to one another. In this example, the connecting board 10 is divided in two, into a first partial connecting board 11 and a second partial connecting board 12. In this arrangement, the two partial connecting boards 11, 12 overlap each other to some extent. This is explained further in relation to FIGS. 8-10.

Also shown is a front lid which, in this view, is situated in the rear part of the electronic device 1. The front lid comprises display and operator control elements as well as data interfaces and power terminals.

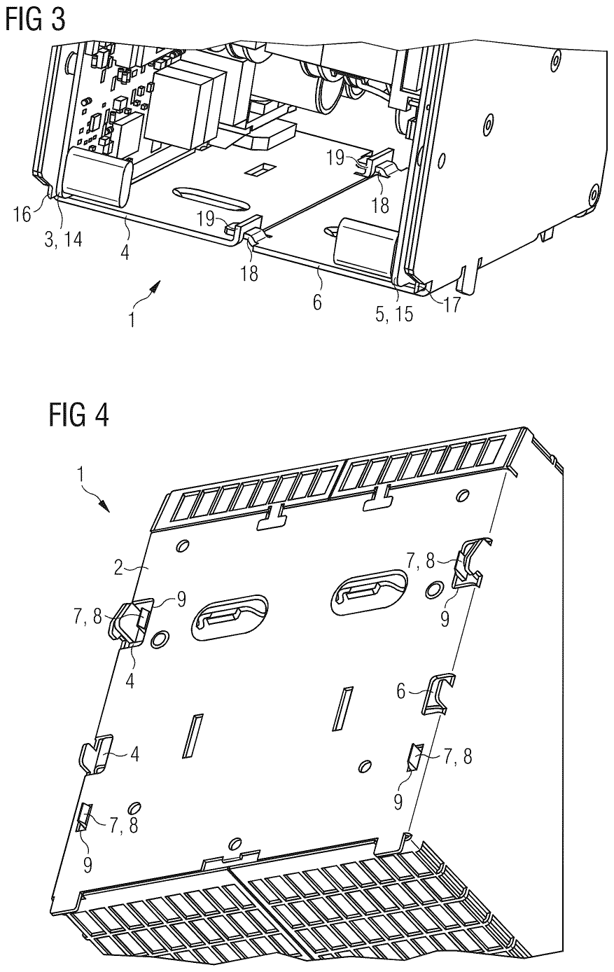

FIG. 3 shows an exemplary constructional layout of an electronic device 1 in accordance with the invention in a third illustration with heatsinks 4, 6 and without housing 2. The diagram serves as a further illustration of the system composed of clip 18 and bracket 19. With the system, mechanical stability is increased before and during the installation of the electronic subassemblies 3, 5 into the housing 2 and the installation is simplified because the electronic subassemblies 3, 5 are movable in one axis only.

FIG. 4 shows an exemplary constructional layout of an electronic device 1 in accordance with the invention in a fourth illustration with heatsinks 4, 6 in a housing 2. A view onto a rear wall of the housing 2 or the electronic device 1 is shown. In this arrangement, the housing 2 or the rear wall of the housing 2 has recesses 9, in this example four recesses 9. The recesses 9 are arranged such that the pressing elements 7 or the plugs 8 are introduced when the electronic subassemblies 3, 5 are inserted into the recesses 9. The bevels of the pressing elements 7 or the plugs 8 assist the insertion. At the same time, the pressing elements 7 or the plugs 8 are pressed outward through the recesses 9 toward the respective sidewalls of the housing 2. This causes the respective electronic subassemblies 3, 5, and in particular the respective heatsinks 4, 6, to be pressed inward against the sidewalls of the housing 2. As a result of this measure, an optimal transfer of heat from the heatsinks 4, 6 to the housing 2 is ensured. In particular, this compensates for mechanical tolerances of the housing 2 that would otherwise prevent the heatsinks 4, 6 from making full contact with the housing 2. In this arrangement, the insulating bodies 16, 17 are made of an insulating material that is elastic and facilitates a pressing action.

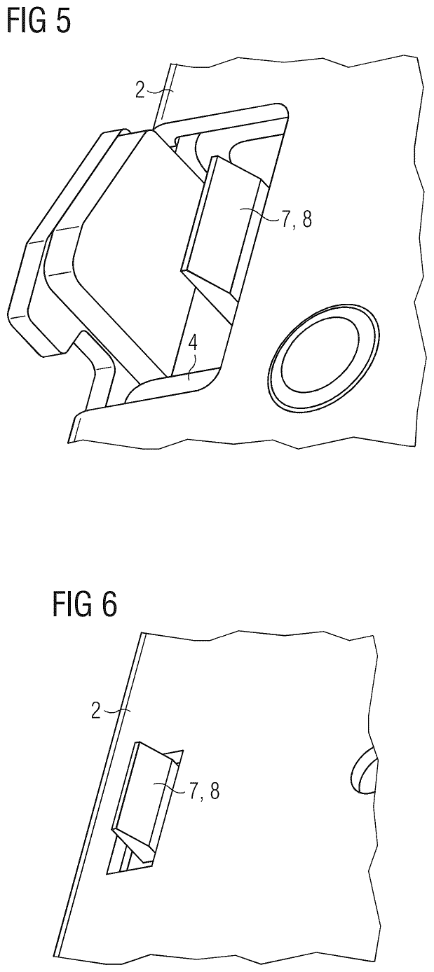

FIGS. 5 and 6 each show an exemplary first and second detail view of a pressing element 7 embodied as a plug 8.

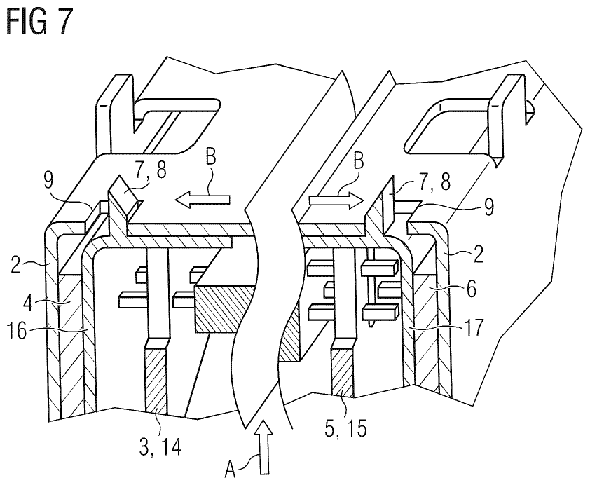

FIG. 7 shows an exemplary illustration of a step of the method for assembling the electronic device 1. Here, how a block substantially consisting of the components shown in FIG. 2, consisting of the electronic subassemblies 3, 5, comprising the heatsinks 4, 6, is inserted into the housing 2 in an assembly direction A is shown. The pressing elements 7, 8, in this example the plugs 8 formed via the insulating bodies 16, 17, interact with recesses 9 in the housing 2. Following their complete insertion, the pressing elements 7, 8 each press the heatsinks 4, 6 in a pressing direction B against the inner sides of the housing 2.

FIG. 8 shows an exemplary illustration of a connecting board 10 having a pressing element 7 formed as a spring element 13. In this arrangement, the connecting board 10 is divided in two, into a first partial connecting board 11 and a second partial connecting board 12. In a non-assembled state, the two partial connecting boards 11, 12 are mounted so as to be movable toward each other and away from each other. In this example, this is realized via extensions that are formed on the partial connecting boards 11, 12. Also incorporated in the first partial connecting board 11 is a pressing element 7 which, in this example, is formed as a spring element 13. In this example, the spring element 13 is formed by the first partial connecting board 11 itself as an elastic extension of the partial connecting board 11. The spring element 13 counteracts a movement of the partial connecting boards 11, 12 and produces a force of the partial connecting boards 11, 12 outward toward the sidewalls of the housing 2 when the partial connecting boards 11, 12 are pressed toward one another. This pressure toward one another is produced when the electronic subassemblies 3, 5 are inserted into the housing 2. The force resulting in this operation acts on the heatsinks 4, 6 via the electronic subassemblies 3, 5, causing the heatsinks 4, 6 to be pressed against the inner sides of the housing. After the electronic subassemblies 3, 5 have been inserted into the housing 2, the partial connecting boards 11, 12 are connected to one another, with the result that these are no longer movable. In this example, the connection is implemented via screwed fittings 20. The screwed fittings also establish an electrical connection between the partial connecting boards 11, 12.

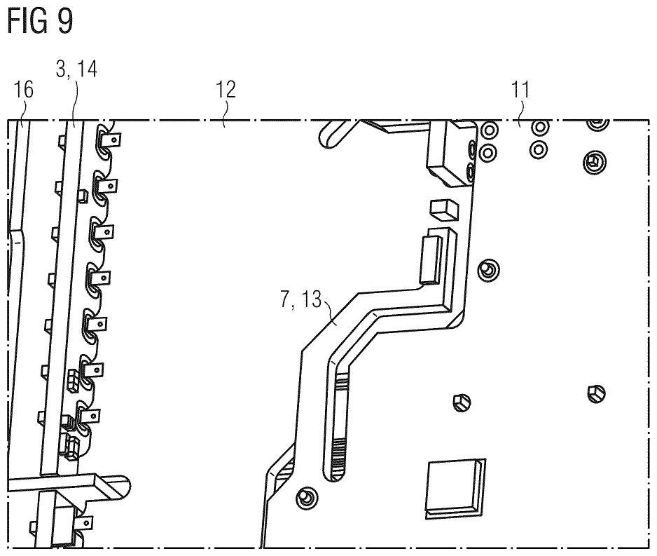

FIG. 9 shows a detailed view of a pressing element 7 formed as a spring element 13. The spring element 13 produces a spring-loaded engagement between the first partial connecting board 11 and the second partial connecting board 12. In this example, the spring element 13 is formed integrated in a single piece as an extension of the first partial connecting board 11.

With the pressing elements 7 formed as plugs 8 it possible to ensure that the heatsinks 4, 6 are pressed in place in a rearward region of the housing 2, while a pressing in place of the heatsinks 4, 6 in a forward region of the housing 2 is ensured by the pressing element 7 formed as a spring element 13.

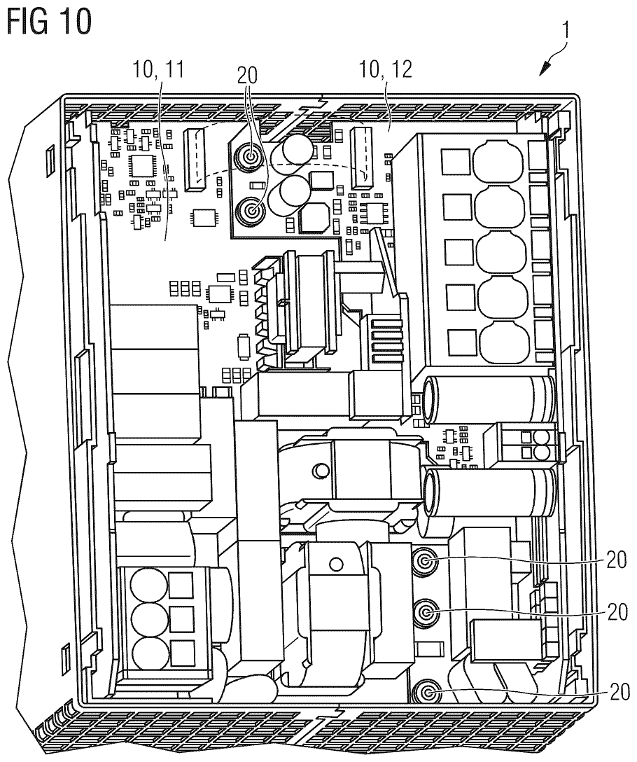

FIG. 10 shows an exemplary illustration of the connecting board 10 of the electronic device 1 with front lid (not shown). The first partial connecting board 11 and the second partial connecting board 12 are shown. The two partial connecting boards 11, 12 are connected to one another via connections 20, in this example via screwed fittings. FIG. 10 thus shows the electronic device 1 in an assembled state. The connections connect the two partial connecting boards mechanically and electrically. Following the connection, a movement of the two partial connecting boards relative to one another is no longer possible. On one of the two partial connecting boards, in this example on the first partial connecting board 11, slotted holes are arranged on the board in the region of the connections 20. On the other of the two partial connecting boards, in this example on the second partial connecting board 12, holes are arranged on the board in the region of the connections 20. The holes and the slotted holes or the region around the holes and the slotted holes can be metallized. The holes and the slotted holes enable the partial connecting boards 11, 12 to be connected following the insertion of the electronic subassemblies 3, 5 into the housing 2 because the combination of hole and slotted hole compensates in each case for a movement of the partial connecting boards 11, 12 relative to one another. With the connections 20, the partial connecting boards 11, 12 are secured or fixed in place relative to one another and an electrical connection to one another is established between the partial connecting boards 11, 12. The connections 20 are introduced after the electronic subassemblies 3, 5 are inserted into the housing 2. Additionally depicted in the upper region of the connecting board 10 is a ribbon cable via which the partial connecting boards are electrically connected in addition.

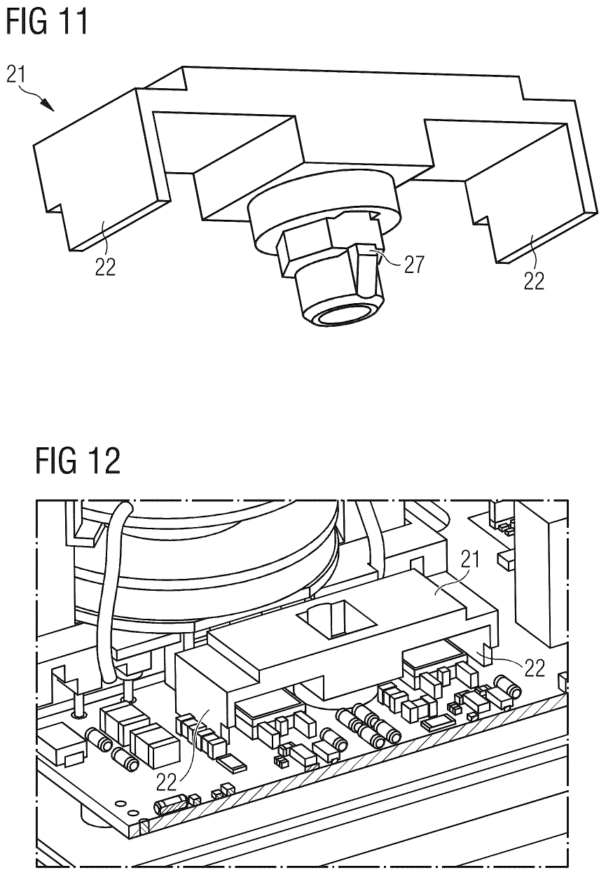

FIG. 11 shows an exemplary first illustration of a first fastening element 21. The first fastening element 21 comprises a body with an internal thread 26 and at least one spring arm 22, in this example two spring arms 22. The first fastening element is an injection-molded part, where the thread may likewise be injection-molded or a die-cast metal thread. The body comprises a part that can be inserted into or through a printed circuit board 14, 15. The part comprises an anti-twist guard, in this example a hexagonal section, and a snap-fit hook 27. When the first fastening element 21 has been inserted into the printed circuit board 14, 15, the hexagonal section is located in a recess of the printed circuit board 14, 15 and serves as an anti-twist guard. In this case, the snap-fit hook is located on a side of the printed circuit board opposite the rest of the first fastening element 21 and prevents the first fastening element 21 from working loose. A recess in which the thread 26 is located extends through the body of the first fastening element 21. The first fastening element 21 can be screwed to the printed circuit board via a side coming from the side of the snap-fit hook 27. In a screwed connection, the spring arms 22 press down onto the printed circuit board 14, 15. Also located on the body of the first fastening element 21 is a step which, like the spring arms 22, bears on the printed circuit board 14, 15 and, when a screwed connection is made, transmits a force onto the printed circuit board 14, 15. In a screwed connection, the spring arms 22 are first pressed down onto the printed circuit board 14, 15 before the step presses down onto the printed circuit board. This has an advantageous effect for the pressing action because the spring arms 22 are structured to be flexible.

FIG. 12 shows an exemplary second illustration of a first fastening element 21.

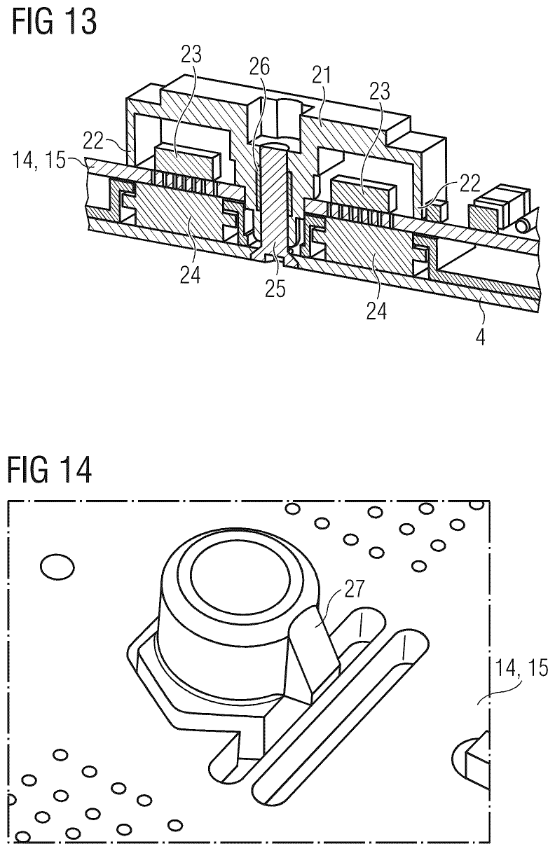

FIG. 13 shows an exemplary third illustration of a first fastening element 21 in a sectional view. The first fastening element 21 is shown with two spring arms 22 and a body with an internal recess in which the thread 26 is located. The first fastening element 21 is secured to a printed circuit board 14, 15. An insulating body 16, 17 is arranged along the printed circuit board 14, 15. The printed circuit board 14, 15 has recesses in which insulation inserts 24 are arranged. The heatsink 4, 6 is arranged along the insulating body 16, 17 and the insulation inserts 24. The insulation inserts 24 are electrically insulating, made of a ceramic material, for example, and make thermal contact with the printed circuit board 14, 15 in areas of increased heat generation, for example, in areas where electronic components 23 are arranged. Electronic components 23 prone to increased heat generation include for example rectifiers or Power Factor Correction (PFC) transistors. Elements providing better heat transfer through the printed circuit board 14, 15 are arranged on the printed circuit board 14, 15 between the electronic components 21 and the insulation inserts 24. These are vias or copper bushes, for example. The spring arms 22 and the body of the first fastening element 21 preferably exert a force onto the printed circuit board 14, 15 itself and thus press the printed circuit board 14, 15 onto the insulation inserts 24. This enables the transfer of heat from electronic components 23 having the most diverse geometric dimensions to be improved without the need to adjust the first fastening element 21 to fit the geometric dimensions.

FIG. 13 further shows a connection of the first fastening element 21 to the arrangement consisting of printed circuit board 14, 15, insulating body 16, 17, insulation inserts 24 and heatsink 4, 6. In this example, a screw 25 is introduced through the heatsink 4, 6 into the thread 26 of the first fastening element 21 and tightened. The snap-fit hook 27 prevents the first fastening element 21 from pressing through out of the printed circuit board 14, 15 and the anti-twist guard prevents the first fastening element from twisting. With the connection, an optimal transfer of heat generated in electronic components 23 is established through the insulation insert 24 to the heatsink 4, 6. It is important that the screwed connection is implemented from a soldering side of the printed circuit board 14, 15. This simplifies the assembly because there is no need to leave any free space for access for assembly tools on a component side of the printed circuit board 14, 15.

FIG. 14 shows an exemplary fourth illustration of a first fastening element 21. In particular, illustrated here is the snap-fit hook 27 that secures the first fastening element 21 in place in the printed circuit board 14, 15. The printed circuit board 14, 15 has a flexible section over which the snap-fit hook 27 slides when being introduced and that returns flexibly to its initial state. The anti-twist guard of the first fastening element 21 is also shown.

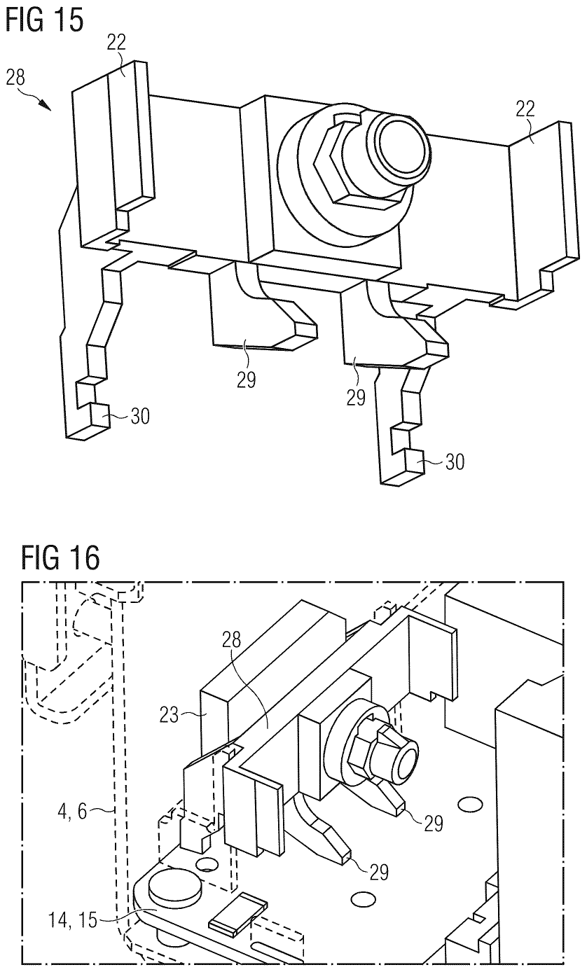

FIG. 15 shows an exemplary first illustration of a second fastening element 28. The second fastening element 28 comprises a body having an internal thread 26. A recess in which the thread 26 is located extends through the body of the second fastening element 28. The recess in the body of the second fastening element 28 extends parallel to the printed circuit board 14, 15 when the second fastening element 28 is mounted on the printed circuit board 14, 15. The second fastening element 28 further comprises at least one support 29 and a hook 30. In this example, the second fastening element 28 comprises two supports 29 and two hooks 30. The second fastening element 28 is mounted laterally on the printed circuit board 14, 15 via the hooks 30. The supports 29 prevent the second fastening element 29 from tilting toward the printed circuit board 14, 15.

FIG. 16 shows an exemplary second illustration of a second fastening element 28. Here, FIG. 16 shows an electronic component 23 that is arranged between the second fastening element 28 and the heatsink 4, 6. The electronic component 23 has an opening (not shown) that passes through the electronic component 23. The electronic component 23 is screwed via a screw (not shown) to the heatsink 4, 6 and the second fastening element. In this arrangement, starting from the heatsink 4, 6, the screw is introduced through the opening in the electronic component 23 into the thread 26 of the second fastening element 28. The supports 29 prevent the second fastening element 28 from tilting toward the printed circuit board 14, 15 when the screwed connection is made. With the screwed connection and the second fastening element 28, the electronic component 23 is pressed against the heatsink 4, 6. The screwed connection from the side of the heatsink 4, 6 facilitates a fabrication or assembly of the electronic device 1 because there is no need to make allowance for free space for tools for making the screwed connection in the region of the printed circuit board 14, 15.

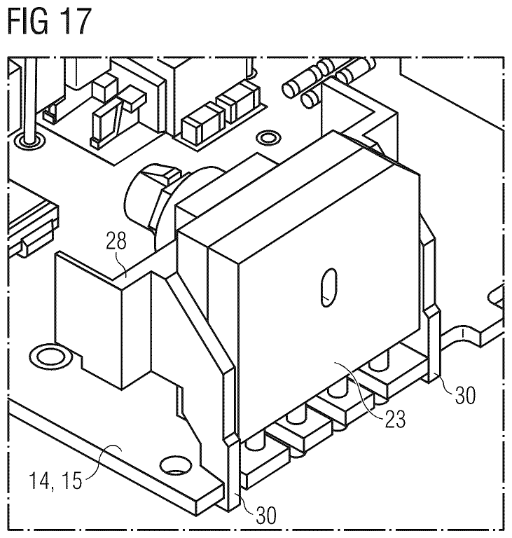

FIG. 17 shows an exemplary third illustration of a second fastening element 28. The second fastening element 28 is shown here in a rearward view with an electronic component 23. Also shown is the opening passing through the electronic component 23. The heatsink 4, 6 and the screw for pressing the electronic component 23 against the heatsink 4, 6 are not shown.

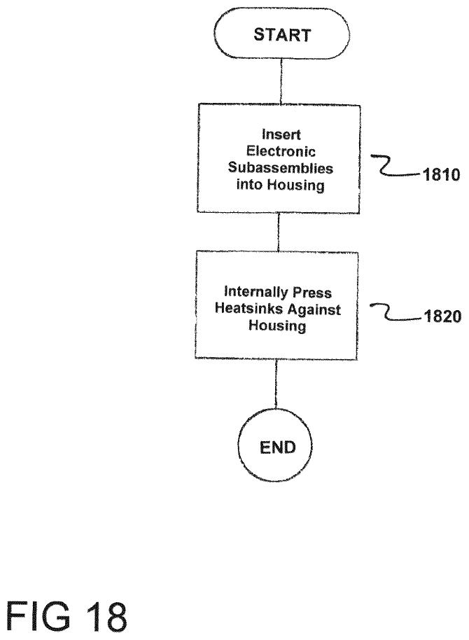

FIG. 18 is a flowchart of the method for assembling an electronic device 1 comprising a housing 2, a first electronic subassembly 3 including a first heatsink 4, and comprising a second electronic subassembly 5 including a second heatsink 6, where the first and the second electronic subassemblies 3, 5 are arranged in the housing 2, and the first heatsink 4 and the second heatsink 6 are pressable internally against the housing 2 via pressing elements 7.

The method comprises inserting the first and the second electronic subassemblies 3, 5 into the housing, as indicated in step 1810.

Next, the first heatsink 4 and the second heatsink 6 are internally pressed against the housing 2 via the pressing elements 7, as indicated in step 1820.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps that perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. An electronic device, comprising:
a housing;
a first electronic subassembly including a first heatsink; and
a second electronic subassembly including a second heatsink;
wherein the first and the second electronic subassembly are arranged in the housing; and
wherein the first heatsink and the second heatsink are pressed internally against the housing via pressing elements.

2. The electronic device as claimed in claim 1, wherein at least one pressing element is formed as a plug which is incorporated in at least one of the first and second electronic subassembly; and wherein the plug interacts with recesses in the housing.

3. The electronic device as claimed in claim 1, further comprising:
a connecting board via which the first and the second electronic subassemblies are electrically and mechanically connected to one another;
wherein at least one pressing element is formed as a spring element which is incorporated in the connecting board.

4. The electronic device as claimed in claim 2, further comprising:
a connecting board via which the first and the second electronic subassemblies are electrically and mechanically connected to one another;
wherein at least one pressing element is formed as a spring element which is incorporated in the connecting board.

5. The electronic device as claimed in claim 3, wherein the connecting board is divided into two boards comprising a first partial connecting board and a second partial connecting board; and wherein the spring element produces a spring-loaded engagement between the first and the second partial connecting boards.

6. The electronic device as claimed in claim 5, wherein the spring element is formed via an elastic extension of the first partial connecting board, said elastic extension interacting with the second partial connecting board.

7. The electronic device as claimed in claim 1, wherein the first and the second heatsinks are pressed against opposite sidewalls of the housing.

8. The electronic device as claimed in claim 1, wherein the first and the second electronic subassemblies have identical electrical functionalities and are connected in parallel.

9. The electronic device as claimed in claim 1, further comprising:
a first fastening element arranged in one of (i) a positive-locking manner in a first printed circuit board of the first electronic subassembly and (ii) a second printed circuit board of the second electronic subassembly, the first fastening element having a thread and at least one spring arm and being screwed to the first or second electronic subassembly such that a force is exerted by the first fastening element via the at least one spring arm, said force pressing one of (i) the first printed circuit board against the first heatsink and (ii) the second printed circuit board against the second heatsink.

10. The electronic device as claimed in claim 1, further comprising:
a second fastening element which is secured laterally to a printed circuit board and via which an electronic component between the heatsink and the second fastening element is pressable against the heatsink.

11. The electronic device as claimed in claim 1, wherein the electronic device comprises a power supply system, the first electronic subassembly comprises a first power supply unit, and the second electronic subassembly comprises a second power supply unit.

12. A method for assembling an electronic device comprising a housing, a first electronic subassembly including a first heatsink, and comprising a second electronic subassembly including a second heatsink, the first and the second electronic subassembly being arranged in the housing, and the first heatsink and the second heatsink being pressable internally against the housing via pressing elements, the method comprising:
inserting the first and the second electronic subassemblies inserted into the housing; and
pressing the first heatsink and the second heatsink internally against the housing via the pressing elements.

13. The method as claimed in claim 12, wherein the electronic device further includes a connecting board via which the first and the second electronic subassemblies are electrically and mechanically connected to one another;
wherein at least one pressing element is formed as a spring element which is incorporated in the connecting board;
wherein the connecting board is divided into two boards comprising a first partial connecting board and a second partial connecting board;
wherein the spring element produces a spring-loaded engagement between the first and the second partial connecting boards; and
wherein the first and the second partial connecting boards are electrically connected to one another.

14. The method as claimed in claim 12, wherein the electronic device further includes a connecting board via which the first and the second electronic subassemblies are electrically and mechanically connected to one another;
wherein at least one pressing element is formed as a spring element which is incorporated in the connecting board;
wherein the connecting board is divided into two boards comprising a first partial connecting board and a second partial connecting board;
wherein the spring element produces a spring-loaded engagement between the first and the second partial connecting boards;
wherein the spring element is formed via an elastic extension of the first partial connecting board, said elastic extension interacting with the second partial connecting board; and
wherein the first and the second partial connecting board are electrically connected to one another.
